(19) United States
(12) Patent Application Publication
(10) Pub. No.: US 2013/0234237 A1
(43) Pub. Date: Sep. 12, 2013

(54) SEMICONDUCTOR POWER DEVICE INTEGRATED WITH CLAMP DIODES HAVING DOPANT OUT-DIFFUSION SUPPRESSION LAYERS

(71) Applicant: Fu-Yuan HSIEH, New Taipei City (TW)

(72) Inventor: Fu-Yuan HSIEH, New Taipei City (TW)

(73) Assignee: FORCE MOS TECHNOLOGY CO. LTD., New Taipei City (TW)

(21) Appl. No.: 13/417,397

(22) Filed: Mar. 12, 2012

(51) Int. Cl. H01L 27/06; H01L 21/20

(52) U.S. Cl. 257/328; 438/481; 257/E27.016; 257/E21.09

(57) ABSTRACT

A semiconductor power device integrated with clamp diodes is disclosed by offering dopant out-diffusion suppression layers to enhance the ESD protection between gate and source, and avalanche capability between drain and source.

### FIELD OF THE INVENTION

This invention generally relates to improved MOSFET (Metal Oxide Semiconductor Field Effect Transistor) configuration or IGBT (Insulated Gate Bipolar Transistor) integrated with a Gate-Source clamp diode for ESD (Electrostatic Discharge) protection between gate and source, and a Gate-Drain clamp diode for avalanche protection between drain and source having dopant out-diffusion suppression layers to benefit the ESD and the avalanche protections.

### BACKGROUND OF THE INVENTION

For a semiconductor power device, for example a trench MOSFET device integrated with a Gate-Source clamp diode, Igss and BVgss are key parameters to measure performance of the Gate-Source clamp diode, wherein the Igss defined by gate-source current at max.Vgs spec (maximum voltage spec between gate and source), e.g. 20V is usually kept below 10 uA and the BVgss is usually defined by the voltage drop between the gate and the source at Igss=300 uA. Besides, the ESD capability is higher when the BVgss is lower because the Gate-Source clamp diode is turned on earlier, therefore, in order to achieve lower BVgss, the Igss is kept at a high level without exceeding the Igss spec of 10 uA.

FIGS. 1A to 1D show some trench MOSFET configurations integrated with Gate-Source clamp diode of prior arts. FIG. 1A illustrates a trench MOSFET 100 disclosed in the prior art of U.S. Pat. No. 6,657,256 (device) and U.S. Pat. No. 6,884,683 (method) wherein an integrated Gate-Source clamp diode comprising multiple back to back Zener diodes composed of alternating doped regions of n+/p/n+ is formed onto a thin oxide layer 101, and is further connected to a source metal 102 on one side while connected to a gate metal 103 on another side via planar diode contact. FIG. 1B illustrates a trench MOSFET 200 disclosed in the prior art of U.S. Pub. No. 2007/0176239 which further comprises a thick oxide layer 202 between the thin oxide layer 201 and the integrated Gate-Source clamp diode comprising multiple back to back Zener diodes composed of alternating doped regions of n+/p/n+/p/n. Besides, the integrated Gate-Source clamp diode in FIG. 1B is connected to the source metal 203 on one side while connected to the gate metal 204 on another side via trenched diode contacts 205 filled with contact metal plugs. FIG. 1C illustrates a trench MOSFET 300 disclosed in the prior art of U.S. Pub. No. 2010/0289073 which further comprises a Nitride layer 307 between the thin oxide layer 301 and the thick oxide layer 302 to prevent body region damage and punch-through issues from happening comparing to FIG. 1B. FIG. 1D illustrates a trench MOSFET 400 disclosed in the prior art of U.S. Pat. No. 7,956,410 wherein the integrated Gate-Source clamp diode is formed onto the thin oxide layer 401 and is connected to the source metal 402 on one side and connected to the gate metal 403 on another side via the trenched diode contacts 404. Beside, underneath each of the trenched diode contacts 404, a buffer trenched gate 406 is formed to act as buffer layer to prevent the gate-body shortage issue from happening.

The prior arts discussed above usually encounter high Igss yield loss due to great Igss standard deviation, please refer to Table 1 wherein a group of experiment data is given. In the condition of prior arts, the yield becomes unstable as result of the Igss out of spec (e.g.>10 uA) when Vgs=20V, therefore in order to keep good yield, the average Igss is kept relatively low, however, the BVgss becomes higher, resulting in low ESD capability. Meanwhile, the high Igss standard deviation (0.40 uA) is due to non-uniform out-diffusion of dopants from the Gate-Source clamp diode during thermal diffusion for source dopant activation such as source anneal for formation of source regions in the trench MOSFET as well as anode and cathode regions in the Gate-Source clamp diode. Therefore, the prior arts encounter a trade-off between the ESD capability and yield due to the limit of the Igss for less power consumption as mentioned above.

Therefore, there is still a need in the art of the semiconductor device configuration, particularly for design and fabrication of trench semiconductor device integrated with Gate-Source clamp diode, to provide a novel cell structure, device configuration and fabrication process that would resolve these difficulties and design limitations.

### SUMMARY OF THE INVENTION

It is therefore an object of the present invention to provide a new an improved semiconductor power device configuration and manufacture method to solve the problems discussed above to benefit yield enhancement and achieve lower power consumption without degrading ESD capability or to enhance ESD capability without sacrificing yield by forming a dopant out-diffusion suppression layer containing Fluorine into upper portion of the Gate-Source clamp diode, wherein the dopant out-diffusion suppression layer comprises multiple alternating doped regions, for example, an array of n*/p*/n*/p*/n* regions formed into the upper portion of the Gate-Source clamp diode comprising an array of n+/p/n+/p/n+ regions in an N-channel trench MOSFET, wherein the n* region is n+ doped containing Fluorine and the p* region is p doped containing Fluorine. From Table 1 it can be seen that, by forming the inventive dopant out-diffusion suppression layer (ion implantation energy is 50 KeV and dose is 5.0E14cm²), the average Igss is reduced about 40% and the Igss standard deviation is reduced about 60% comparing with the prior arts while the average BVgss and the BVgss standard deviation is slightly reduced. The experiment results indicate that this invention benefits yield enhancement and low power consumption due to low Igss without degrading the ESD capability or enhances the ESD capability by increasing the Igss without sacrificing yield due to low Igss standard deviation.

According to one aspect of the present invention, there is provided a semiconductor power device in an epitaxial layer of a first conductivity type and integrated with an Gate-Source clamp diode comprising multiple back to back Zener diodes composed of alternating doped regions of the first conductivity type next to a second conductivity type, further comprising: a dopant out-diffusion suppression layer formed into upper portion of the Gate-Source clamp diode, wherein the dopant out-diffusion suppression layer containing Fluorine and comprising multiple doped regions alternating doped of the first conductivity type next to the second conductivity type.

According to another aspect of the present invention, the semiconductor power device integrated an Gate-Source clamp diode further comprises a thin dielectric layer along outer surface of the Gate-Source clamp diode, wherein the thin dielectric layer is formed before ion implantation for source or before source dopant activation of the semiconductor power device and to further reduce the dopant out-diffusion from the Gate-Source clamp diode. The thin dielectric layer can be implemented by using oxide or Nitride or oxynitride.

In some preferred embodiments, the present invention can be implemented including one or more following features: the Gate-Source clamp diode is disposed on a thin oxide layer over the epitaxial layer; the Gate-Source clamp diode is disposed on a thick oxide/thin oxide layer over the epitaxial layer; the Gate-Source clamp diode is disposed on a thick oxide/Nitride/thin oxide layer over the epitaxial layer; the Gate-Source clamp diode is connected to a source metal of the semiconductor power device on one side and connected to a gate metal of the semiconductor power device on another side via planar diode contact; the Gate-Source clamp diode is connected to a source metal of the semiconductor power device on one side and connected to a gate metal of the semiconductor power device on another side via trenched diode contact filled with contact metal plug; the Gate-Source clamp diode being disposed on a thin oxide layer over the epitaxial layer which further comprising a buffer trenched gate underneath each the trenched diode contact; each the trenched diode contact is penetrating through the dopant out-diffusion suppression layer and extending into the Gate-Source clamp diode.

According to another aspect, this invention further discloses a method for manufacturing a semiconductor power device integrated with an Gate-Source clamp diode comprising: depositing an un-doped poly-silicon layer onto an epitaxial layer; carrying out ion implantation of a second conductivity type to make the poly-silicon layer dope with the second conductivity type; carrying out Fluorine ion implantation to make the upper portion of the poly-silicon layer contain Fluorine. To manufacture other preferred embodiment, the method further comprises depositing a thin dielectric layer covering outer surface of the poly-silicon layer of the second conductivity type after Fluorine ion implantation.

Another aspect of the present invention, there is provided a MOSFET device in an epitaxial layer of a first conductivity type and integrated with an Gate-Source clamp diode and Gate-Drain clamp diode comprising multiple back to back Zener diodes composed of alternating doped regions of the first conductivity type next to a second conductivity type, further comprising: a dopant out-diffusion suppression layer formed into upper portion of the Gate-Source clamp diode, wherein the dopant out-diffusion suppression layer containing Fluorine and comprising multiple doped regions alternating doped of the first conductivity type next to the second conductivity type.

Another aspect of the present invention, there is provided an IGBT device integrated with an Gate-Source clamp diode and Gate-Drain clamp diode comprising multiple back to back Zener diodes composed of alternating doped regions of a first conductivity type next to a second conductivity type, further comprising: a dopant out-diffusion suppression layer formed into upper portion of the Gate-Source clamp diode, wherein the dopant out-diffusion suppression layer containing Fluorine and comprising multiple doped regions alternating doped of the first conductivity type next to the second conductivity type.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1A is a side cross-sectional view of a semiconductor power device integrated with an Gate-Source clamp diode disclosed in a prior art.

FIG. 1B is a side cross-sectional view of a semiconductor power device integrated with an Gate-Source clamp diode disclosed in another prior art.

FIG. 1C is a side cross-sectional view of a semiconductor power device integrated with an Gate-Source clamp diode disclosed in another prior art.

FIG. 1D is a side cross-sectional view of a semiconductor power device integrated with an Gate-Source clamp diode disclosed in another prior art.

FIG. 2 is a side cross-section view of a preferred embodiment according to the present invention.

FIG. 3 is a side cross-section view of another preferred embodiment according to the present invention.

FIG. 4 is a side cross-section view of another preferred embodiment according to the present invention.

FIG. 5 is a side cross-section view of another preferred embodiment according to the present invention.

FIG. 6 is a side cross-section view of another preferred embodiment according to the present invention.

FIGS. 7A to 7G are a serial of side cross-sectional views for showing the process steps for fabricating a semiconductor device integrated with an Gate-Source clamp diode in FIG. 6.

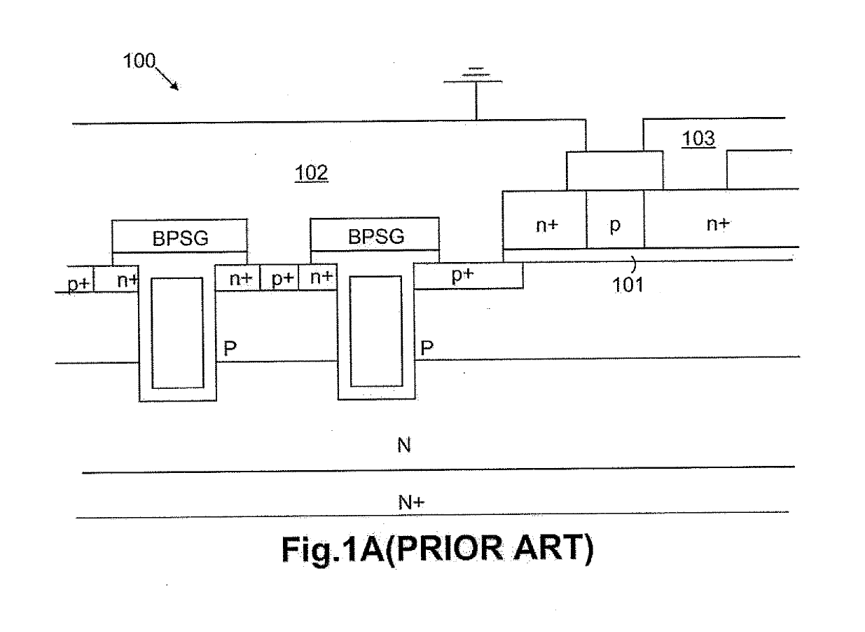

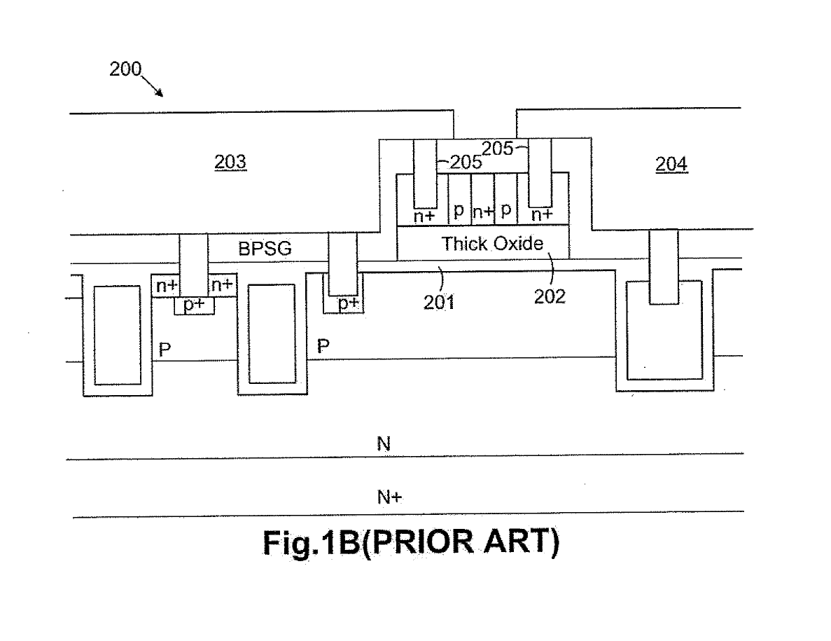

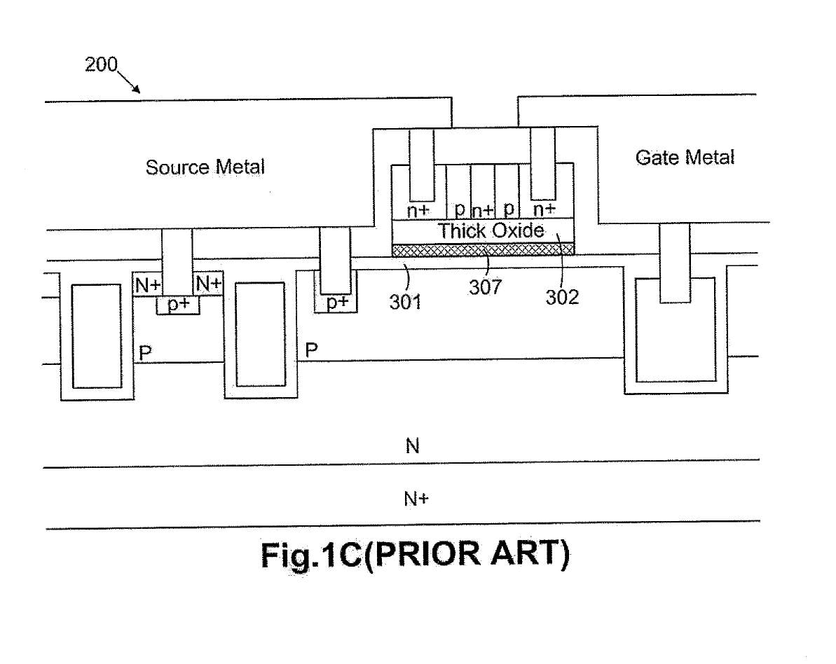

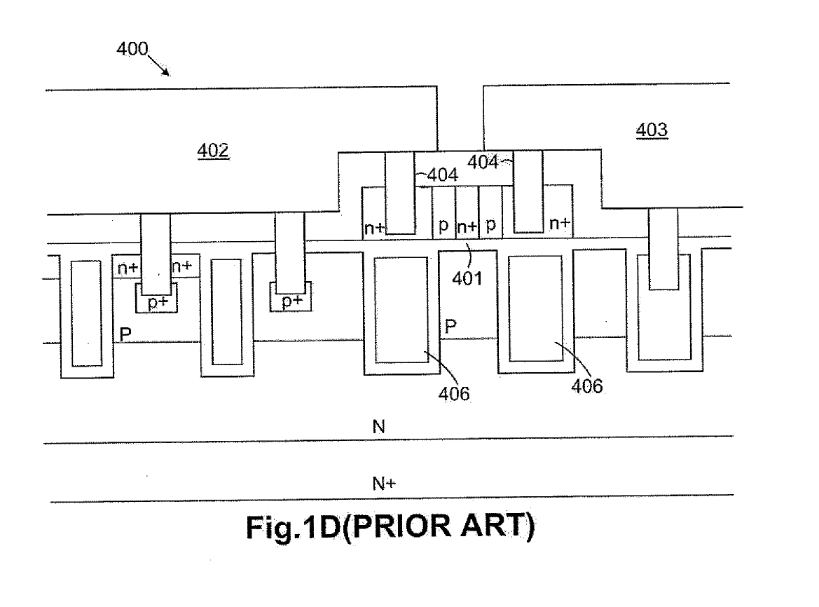

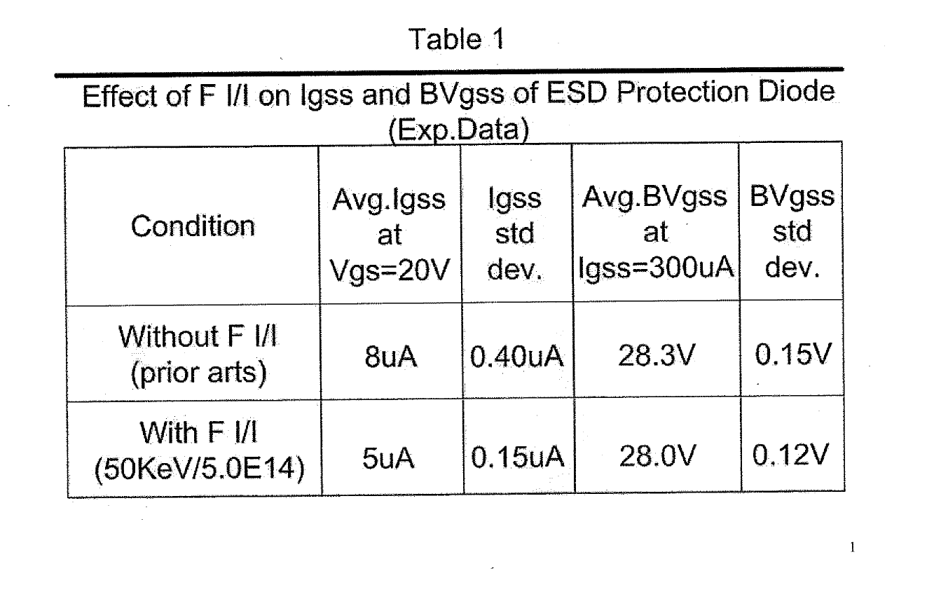

### DETAILED DESCRIPTION OF THE EMBODIMENTS

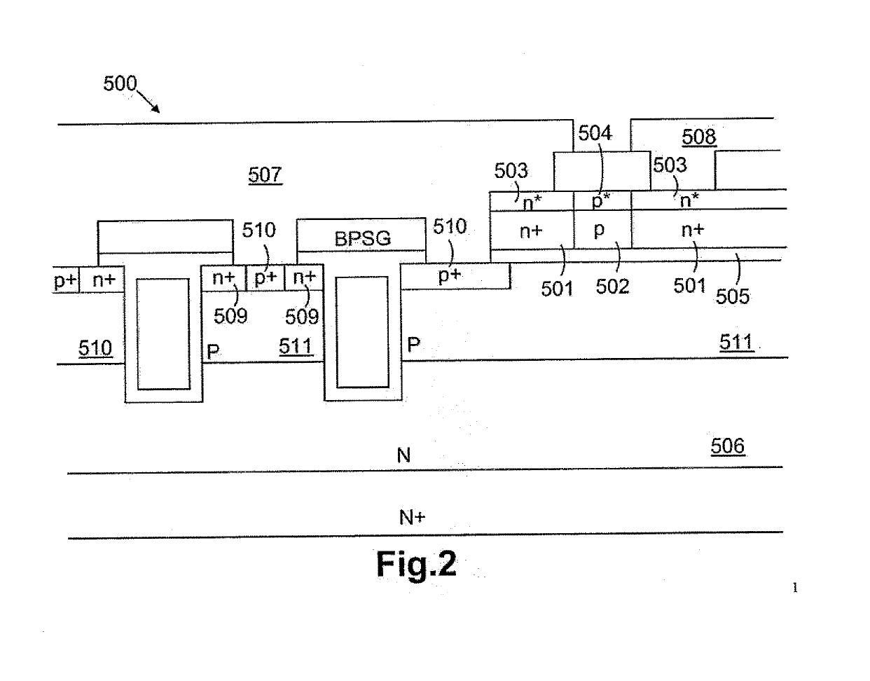

Please refer to FIG. 2 for a preferred embodiment in which an N-channel trench MOSFET 500 integrated with an Gate-Source clamp diode is disclosed, wherein the Gate-Source clamp diode comprises an array of alternating doped regions of n+ region 501 and p region 502. According to the present invention, an dopant out-diffusion suppression layer is formed into the upper portion of the Gate-Source clamp diode, composed of an array of alternating doped regions of n* region 503 and p* region 504, wherein the n* region 503 formed above the n+ region 501 is n+ doped containing Fluorine, and the p* region 504 formed above the p region 502 is p doped containing Fluorine. Furthermore, the Gate-Source clamp diode formed on a thin oxide layer 505 over an N epitaxial layer 506 is connected to a source metal 507 of the trench MOSFET 500 on one side and to a gate metal 508 of the trench MOSFET 500 on another side via planar diode contacts, wherein the source metal 507 is also contacting with n+ source regions 509 and p+ body contact regions 510 formed in P body regions 511 of the trench MOSFET 500.

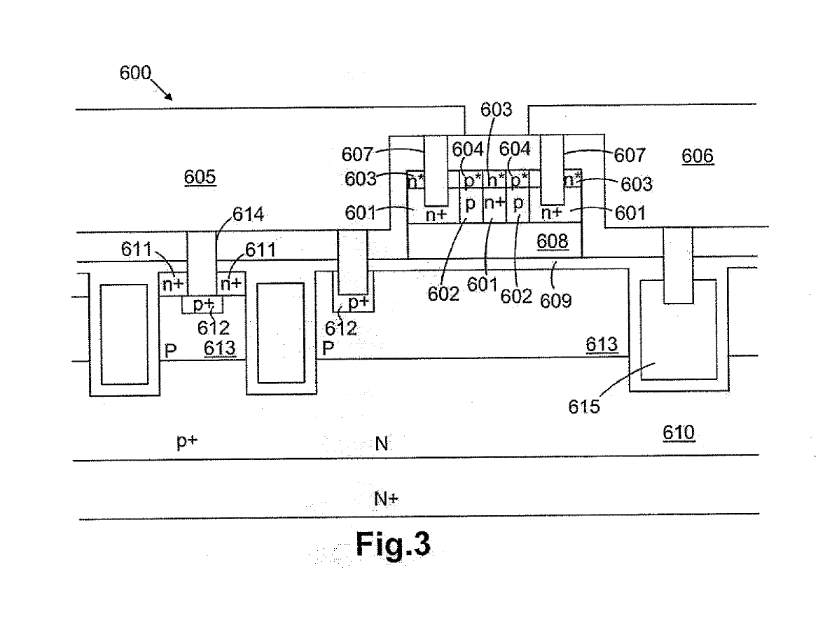

Please refer to FIG. 3 for another preferred embodiment in which an N-channel trench MOSFET 600 integrated with an Gate-Source clamp diode is disclosed, wherein the Gate-Source clamp diode comprises an array of alternating doped regions of n+ region 601 and p region 602. According to the present invention, an dopant out-diffusion suppression layer is formed into the upper portion of the Gate-Source clamp diode, composed of an array of alternating doped regions of n* region 603 and p* region 604, wherein the n* region 603 formed above the n+ region 601 is n+ doped containing Fluorine, and the p* region 604 formed above the p region 602 is p doped containing Fluorine. Different from FIG. 2, the Gate-Source clamp diode is connected to the source metal 605 on one side and to the gate metal 606 on another side via trenched diode contact 607 which is filled with contact metal plug, for example tungsten plug and penetrating through the n* region 603 and extending into the n+ region 601. For prevention of over-etch issue when forming the trenched diode contact 607, a thick oxide layer 608 is offered underneath the Gate-Source clamp diode and onto the thin oxide layer 609 overlying the N epitaxial layer 610. Meanwhile, the source metal 605 is also contacting with the source regions 611 and the p+ body contact regions 612 formed in the P body regions 613 via trenched source-body contacts 614 filled with the contact metal plug, and the gate metal 606 is also contacting with a trenched gate 615 for gate connection.

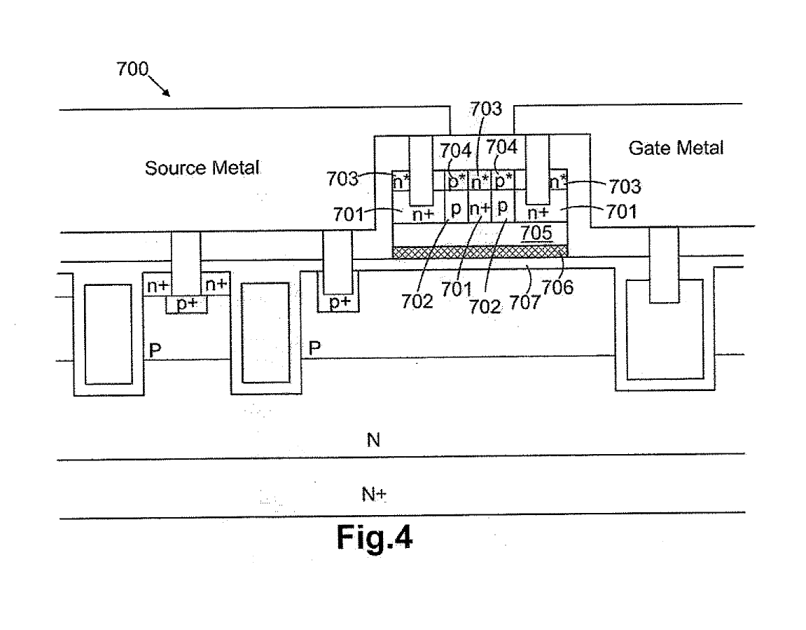

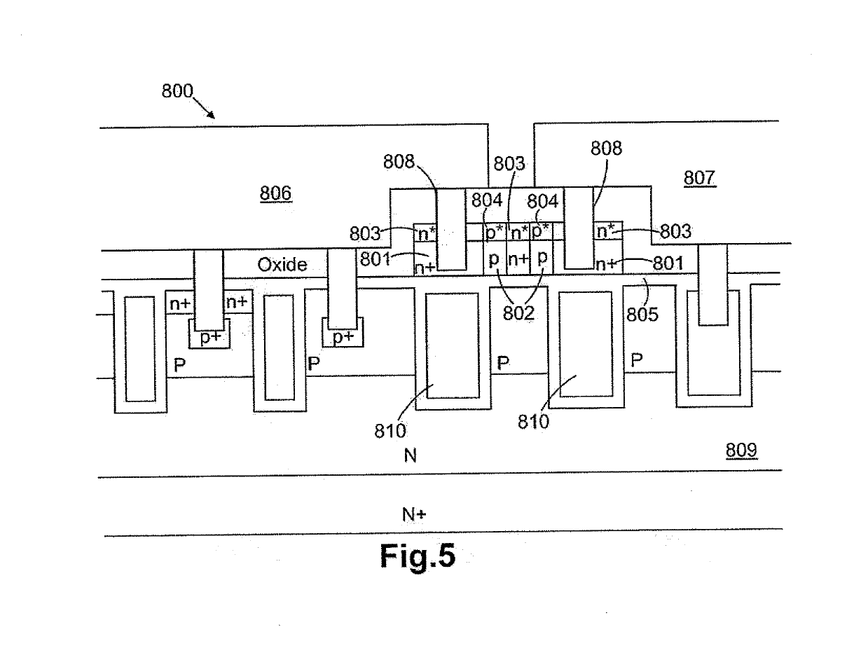

Please refer to FIG. 4 for another preferred embodiment in which an N-channel trench MOSFET 700 integrated with an Gate-Source clamp diode is disclosed, wherein the Gate-Source clamp diode comprises an array of alternating doped regions of n+ region 701 and p region 702. According to the present invention, an dopant out-diffusion suppression layer is formed into the upper portion of the Gate-Source clamp diode, composed of an array of alternating doped regions of n* region 703 and p* region 704, wherein the n* region 703 formed above the n+ region 701 is n+ doped containing Fluorine, and the p* region 704 formed above the p region 702 is p doped containing Fluorine. The configuration illustrated in FIG. 5 has a similar structure with FIG. 4 except that, underneath the thick oxide layer 705 onto which formed the Gate-Source clamp diode, a Nitride layer 706 is introduced on the thin oxide layer 707.

Please refer to FIG. 5 for another preferred embodiment in which an N-channel trench MOSFET 800 integrated with a Gate-Source clamp diode is disclosed, wherein the Gate-Source clamp diode comprises an array of alternating doped regions of n+ region 801 and p region 802. According to the present invention, an dopant out-diffusion suppression layer is formed into the upper portion of the Gate-Source clamp diode, composed of an array of alternating doped regions of n* region 803 and p* region 804, wherein the n* region 803 formed above the n+ region 801 is n+ doped containing Fluorine, and the p* region 804 formed above the p region 802 is p doped containing Fluorine. The Gate-Source clamp diode formed on the thin oxide layer 805 is connected to the source metal 806 on one side and to the gate metal 807 on another side via the trenched diode contact 808 filled with contact metal plug. In the N epitaxial layer 809, a buffer trenched gate 810 is formed underneath each the trenched diode contact 808 to prevent the damage caused by over-etch when forming the trenched diode contact 808.

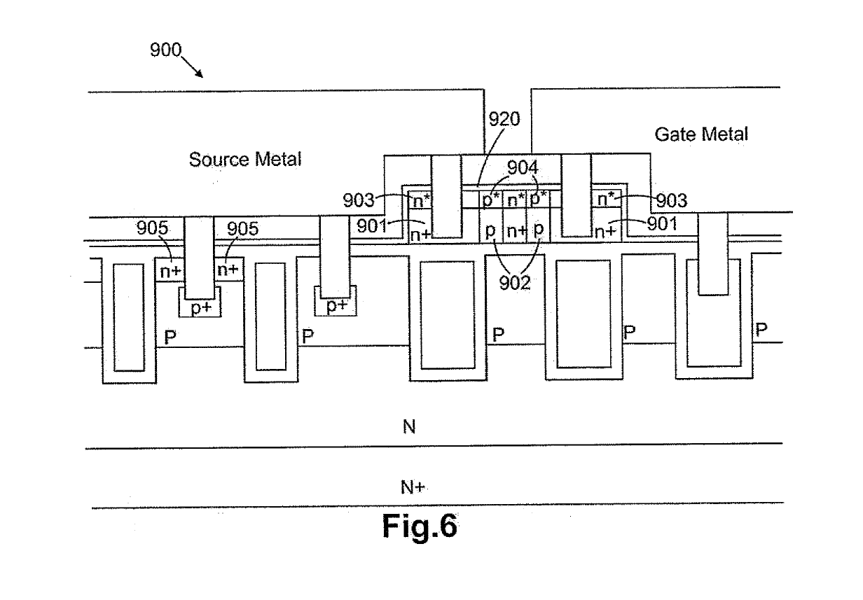

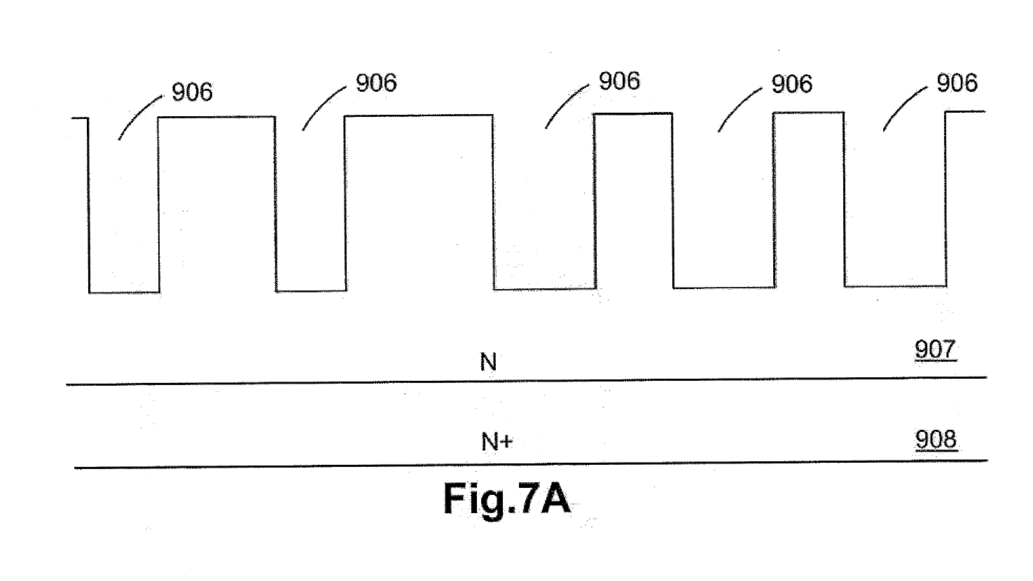

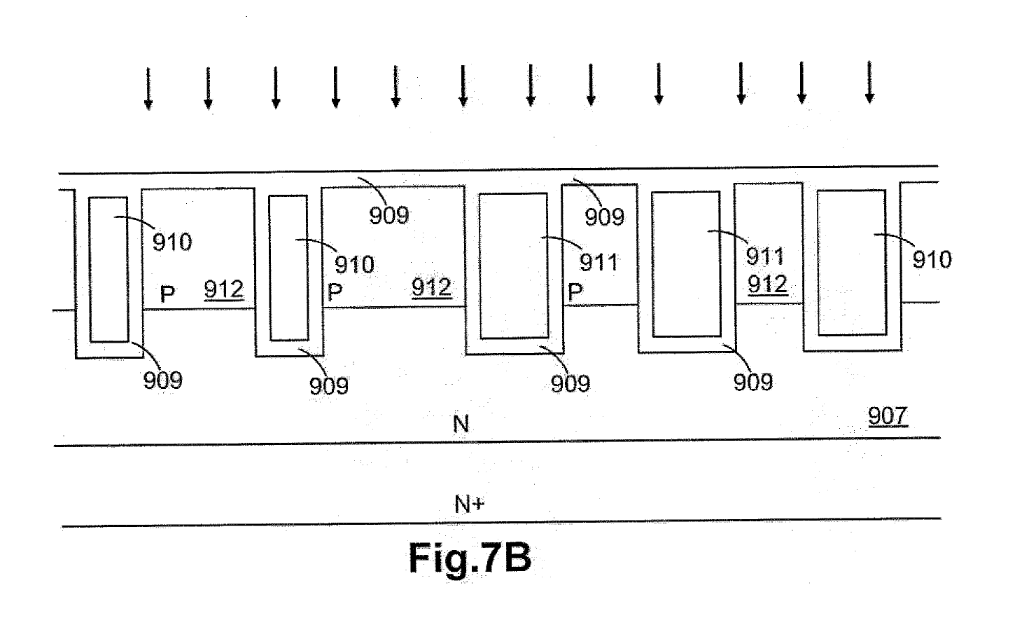

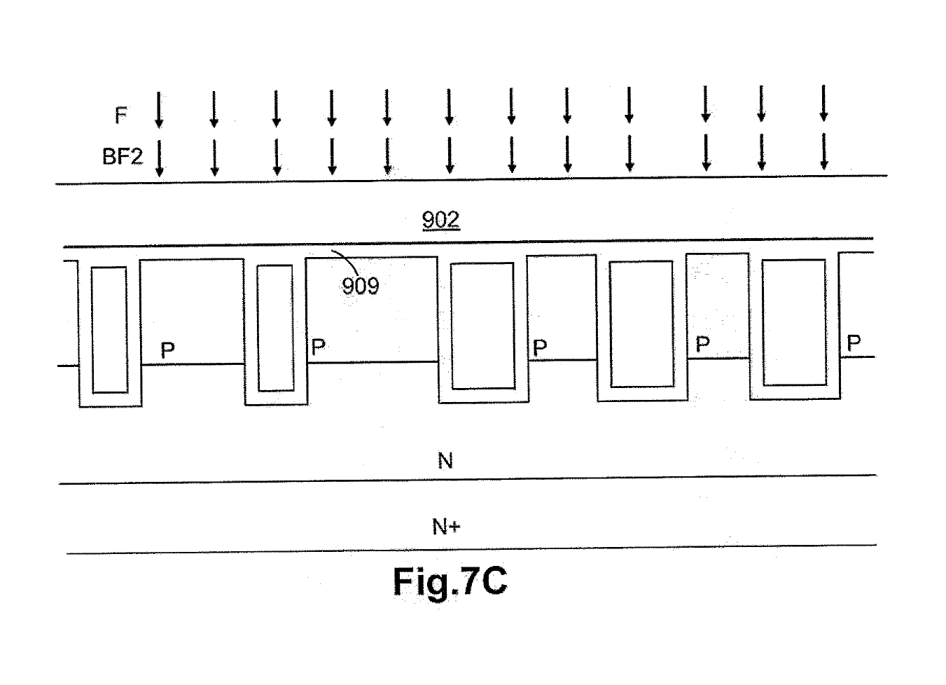

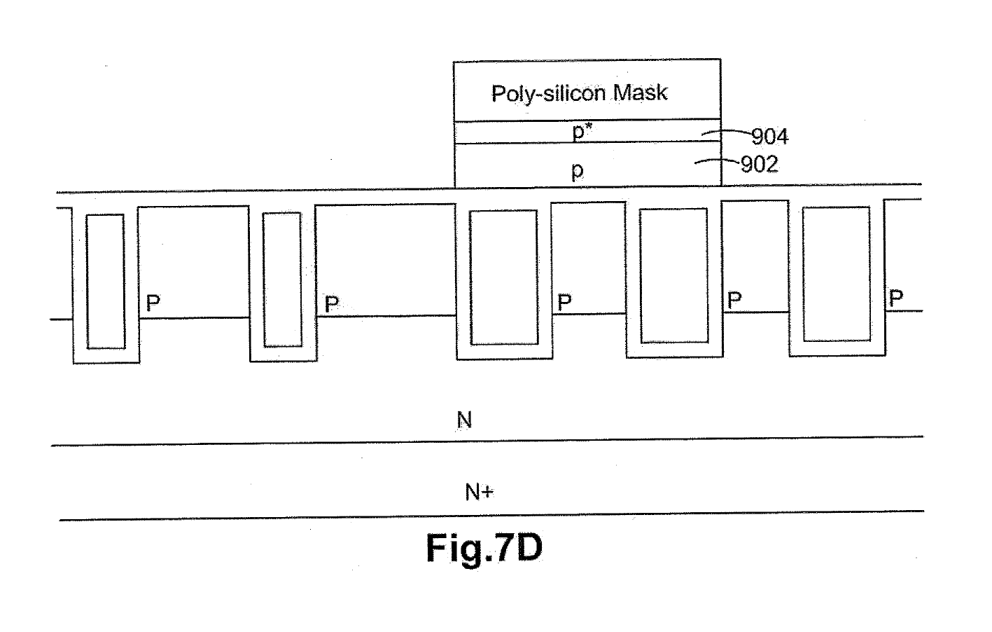

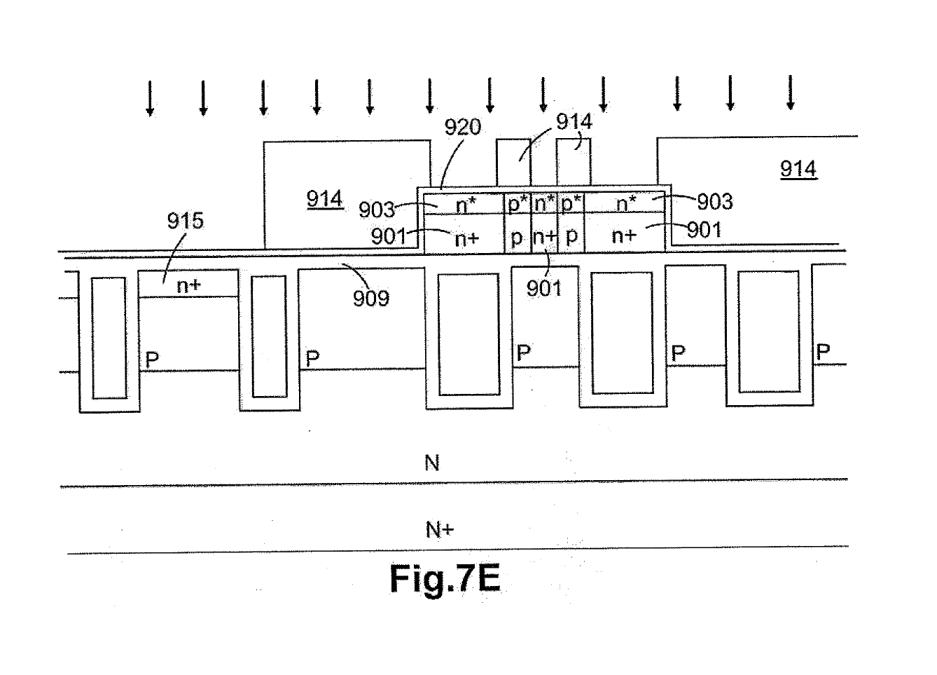

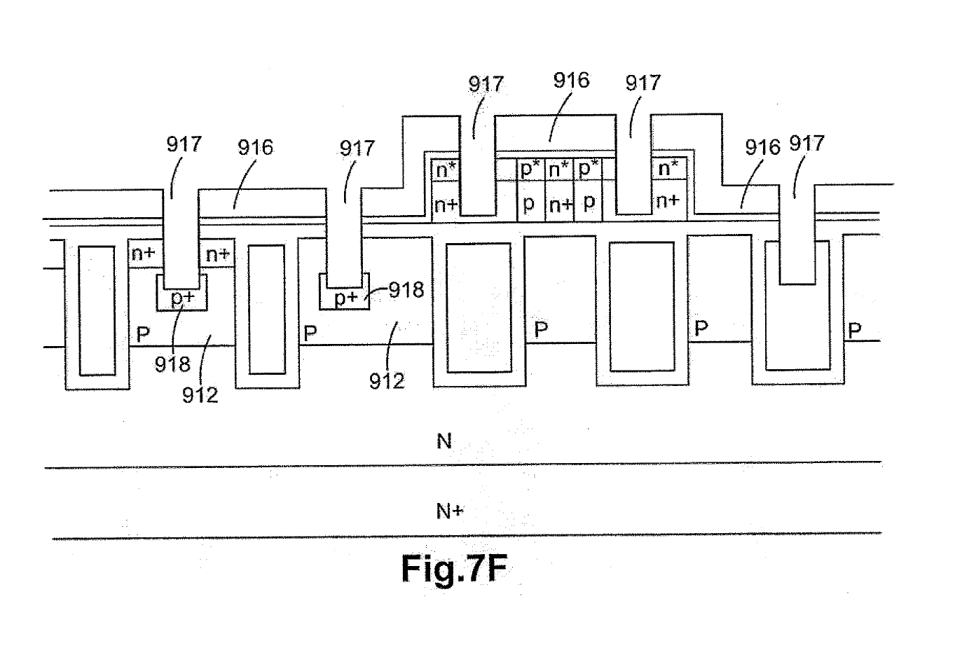

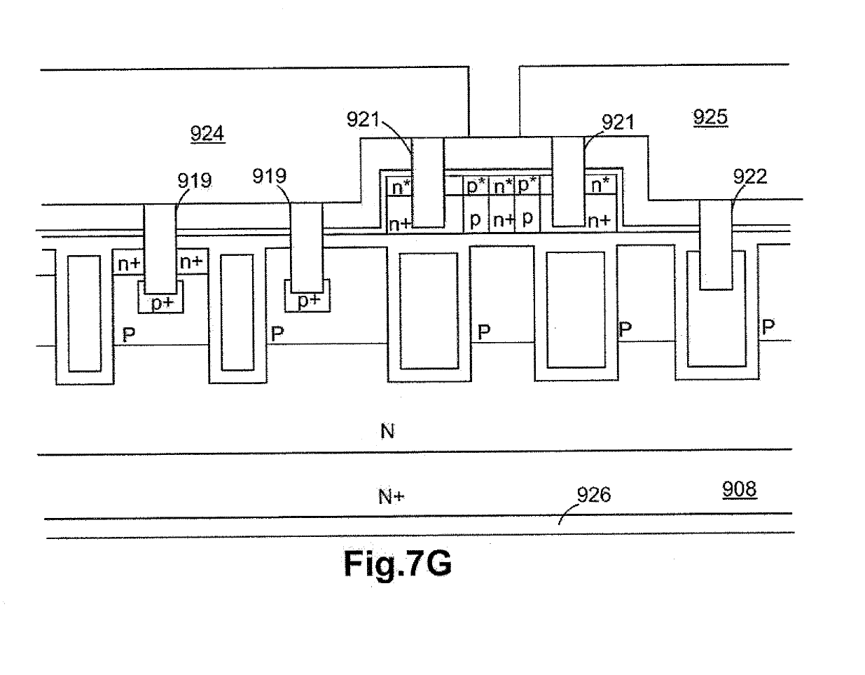

Please refer to FIG. 6 for another preferred embodiment in which an N-channel trench MOSFET 900 integrated with an Gate-Source clamp diode is disclosed, wherein the Gate-Source clamp diode comprises an array of alternating doped regions of n+ region 901 and p region 902. According to the present invention, an dopant out-diffusion suppression layer is formed into the upper portion of the Gate-Source clamp diode, composed of an array of alternating doped regions of n* region 903 and p* region 904, wherein the n* region 903 formed above the n+ region 901 is n+ doped containing Fluorine, and the p* region 904 formed above the p region 902 is p doped containing Fluorine. The configuration illustrated in FIG. 7 has a similar structure with FIG. 6 except that, a thin dielectric layer 920 of oxide or Nitride or oxynitride is formed along outer surface of the Gate-Source clamp diode. The thin dielectric layer 920 is deposited before ion implantation for the n+ source regions 905 of the trench MOSFET 900 and for the n+ region 901 and the n* regions 903 to further reduce the dopant out-diffusion from the Gate-Source clamp diode.

Please refer to FIG. 7A to 7G for a serial of side cross-section views to illustrate the fabricating steps of the configuration shown in FIG. 6. In FIG. 7A, a trench mask (not shown) is applied to open a plurality of gate trenches 906 in an N epitaxial layer 907 supported on an N+ substrate 908 by employing a dry silicon etch process. Then, the gate trenches 906 all oxidized with a sacrificial oxide (not shown) to eliminate the plasma damage during the process of etching the gate trenches by removing the sacrificial oxide. In FIG. 7B, a gate oxide layer 909 is grown along inner surface of the gate trenches and along top surface of the N epitaxial layer 907, followed by depositing a doped poly-silicon layer filling in the gate trenches. Next, the filling-in doped poly-silicon layer is etched back or CMP (Chemical Mechanical Polishing) to form a plurality of trenched gates 910 and buffer trenched gates 911. Then, the manufacturing process proceeds with a P-type dopant ion implantation and an elevated temperature is applied to diffuse P body regions 912 into the N epitaxial layer 907.

In FIG. 7C, an un-doped poly-silicon layer 902 is deposited on top of the thin oxide 909, followed by a p-type dopant implant with a blank Boron dopant. Next, a step of Fluorine implant is carried out to form a dopant out-diffusion suppression layer into upper portion of the poly-silicon layer 902. Therefore, the poly-silicon layer is now p region 902 and the upper portion of the poly-silicon layer is p* region 904 containing Fluorine, as illustrated in FIG. 7D. Then, a photo resist is applied as a poly-silicon mask to etch the p* region 904 and the p region 902 by dry silicon etch. In FIG. 7E, after the removal of the photo resist in FIG. 7D, a thin dielectric layer 920 of oxide layer or Nitride or oxynitride is deposited covering outer surface of the poly-silicon layer and onto the thin oxide layer 909 to act as another dopant out-diffusion suppression layer. Then, after applying a source mask 914, an Arsenic or Phosphorus ion implantation is carried out above the whole device followed by a source dopant activation step to form an n+ source region 915 for the trench MOSFET, and to form multiple n+ regions 901 for an Gate-Source clamp diode while to form multiple n* regions 903 containing Fluorine for the dopant out-diffusion suppression layer.

In FIG. 7F, an oxide interlayer 916 is deposited onto the thin dielectric layer 920. Then, after applying a contact mask (not shown), a plurality of contact trenches 917 are etched. Next, a BF2 implant is carried out to form a p+ body contact region 918 underneath each the contact trench 917 extending into the P body region 912.

In FIG. 7G, a tungsten plug is filled into each the contact trench after the deposition of a barrier metal layer composed of Ti/TiN or Co/TiN along inner surface of each the contact trench and then etched back or CMP to form trenched source-body contact 919, trenched diode contact 921 and trenched gate contact 922. Next, a front metal layer is deposited and then patterned by a metal mask (not shown) to form a source metal 924 and a gate metal 925 by metal etch. Then, after grinding back side of the N+ substrate 908, a back metal of Ti/Ni/Ag is deposited thereon to act as drain metal 926.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A semiconductor power device integrated with at least a clamp diode comprising multiple back to back Zener diodes composed of alternating doped regions of a first conductivity type next to a second conductivity type, further comprising:
a dopant out-diffusion suppression layer containing Fluorine formed into upper portion of said clamp diode having alternating doped regions of said first conductivity type next to said second conductivity type.

2. The semiconductor power device of claim 1, wherein said claim diode is disposed on a thin oxide layer above a semiconductor substrate.

3. The semiconductor power device of claim 1, wherein said claim diode is disposed on a thick oxide/thin oxide layer above a semiconductor substrate.

4. The semiconductor power device of claim 1, wherein said ESD claim diode is disposed on a thick oxide/Nitride/thin oxide layer above a semiconductor substrate.

5. The semiconductor power device of claim 2, further comprises a buffer trenched gate underneath each of trenched diode contacts penetrating through said dopant out-diffusion suppression layer and extending into lower portion of said clamp diode.

6. The semiconductor power device of claim 5, wherein said trench diode contacts are filled with a tungsten contact metal plug padded by a barrier metal layer of Ti/TiN or Co/TiN.

7. The semiconductor power device of claim 1 further comprises a thin dielectric layer deposited on outer surface of said Gate-Source clamp diode before source dopant activation.

8. The semiconductor power device of claim 7, wherein said thin dielectric layer is oxide layer, Nitride or oxynitride.

9. The semiconductor power device of claim 1 is MOSFET.

10. The semiconductor power device of claim 1 is IGBT.

11. The semiconductor power device of claim 1 integrates with a Gate-Source clamp diode for gate-source ESD protection and a Gate-Drain clamp diode for drain-source avalanche protection.

12. The semiconductor power device of claim 1 integrates with a Gate-Source clamp diode only.

13. The semiconductor power device of claim 1 wherein said first conductivity type is N type doped with Arsenic or phosphorus dopant and said second conductivity type is P type doped with boron dopant.

14. A method for manufacturing a semiconductor power device integrated with at least a clamp diode, comprising:
depositing an un-doped poly-silicon layer over a dielectric layer above a semiconductor substrate;
carrying out a dopant implant of a first conductivity type into said un-doped poly-silicon; and
carrying out a Fluorine implant to make the upper portion of said poly-silicon layer contain Fluorine before activation of source dopant of a second conductivity type.

15. The method of claim 14 further comprising depositing a thin dielectric layer covering outer surface of said poly-silicon layer of said second conductivity type after Fluorine implant before said source dopant activation.
